(19) United States
(12) Patent Application Publication
(10) Pub. No.: US 2026/0149406 A1
(43) Pub. Date: May 28, 2026

(54) EQUIPPING A CONVEYING UNIT DURING THE MANUFACTURING OF SOLAR PANELS

(71) Applicant: M10 Solar Equipment GmbH, Freiburg (DE)

(72) Inventors: Philipp Donatus Martin ZAHN, Freiburg (DE); Günter SCHNEIDEREIT, Freiburg (DE); Dominique JEHL, Rhinau (FR)

(73) Assignee: M10 Solar Equipment GmbH, Freiburg (DE)

(21) Appl. No.: 18/280,506

(22) PCT Filed: Feb. 1, 2022
(86) PCT No.: PCT/EP2022/052330

§ 371 Date: Sep. 6, 2023

(30) Foreign Application Priority Data
Mar. 11, 2021 (DE) 10 2021 105 987.9

(51) Int. Cl. H10F 71/00

(52) U.S. Cl. CPC H10F 71/1375

(57) ABSTRACT

A method for producing solar modules is described, wherein solar elements are combined to form rows, wherein each row includes at least two solar elements, wherein the solar modules are constructed from electrically interconnected rows, wherein, for the equipping of the solar module, at least two rows are picked up in one operation and held ready at different heights above the solar module, and wherein, for the equipping of the solar module, the rows are lowered together in each case only to the extent that only the respective row currently to be equipped contacts the solar module.

### CROSS-REFERENCE TO RELATED APPLICATIONS

This application is a 371 National Phase of PCT/EP 2022/052330, filed Feb. 1, 2022, which claims priority from German Patent Application No. 10 2021 105 987.9, filed Mar. 11, 2021, the entire contents of which are incorporated herein by reference as if fully set forth.

### TECHNICAL FIELD

The invention relates to a method for producing solar modules, wherein solar elements are combined to form rows, wherein each row comprises at least two solar elements and wherein the solar modules are constructed from electrically interconnected rows.

### BACKGROUND

The solar elements which are combined to form rows may be solar cells, photovoltaic solar cells, photovoltaic cells or partially sectioned parts thereof, what is known as shingle, that is to say for example solar cell shingle or photovoltaic cell shingle.

In such a method, individual solar elements or basic elements of a solar cell may be passed in rows onto a transfer unit, the transfer unit may be displaced into an assembling region and in the assembling region the solar elements may be deposited in rows on a tray or another conveying unit, in particular a motorized conveying unit. The depositing of the solar element on the motorized conveying unit for provision of a solar module is also referred to as equipping the solar module. The assembling region is therefore also referred to as equipping, mounting or construction region.

For the equipping of the solar module, in particular of a one-piece solar module, the rows, that is to say the rows of solar elements or solar elements arranged in rows, may be arranged so as to overlap one another along a longitudinal axis of two rows arranged next to one another. In the region of overlap, an adhesive or another fastening means for connecting the rows arranged next to one another may be applied. The adhesive may be applied, for example, to the solar elements or to the rows located on the transfer unit. For the application of the adhesive, delivery units may be used. By way of example, dispensers which can carry out linear applications of adhesive may be used. As an alternative, the adhesive may be applied by a printing apparatus. By way of example, the adhesive may be applied by means of a printing method, such as web-fed printing or screen printing. The rows provided with the adhesive may be aligned with one another and connected to one another on the motorized conveying unit and thus be combined to form a solar module.

US 2016/163914 A1 and US 2018/175233 A1 describe systems and methods for producing solar modules.

In such methods, the time required between the provision of an individual solar element and the equipping of a solar module with the individual solar element, also referred to as the cycle time, plays a decisive role. A shortened cycle time leads to a considerable shortening of the processing time for producing the entire solar module. The object on which the invention is based is therefore to increase the efficiency of a method for producing solar modules, in particular to accelerate such a method.

In the case of the method of the type mentioned in the introduction, this object is achieved according to the invention in particular in that, for the equipping of the solar module, at least two rows are picked up in one operation and held ready at different heights above the solar module, and in that, for the equipping of the solar module, the rows are lowered together in each case only to the extent that only the respective row currently to be equipped contacts the solar module.

### SUMMARY

The invention is based on the realization that the cycle time can be shortened by simultaneously carrying out individual method steps for a plurality of solar cells. By way of example, in the method according to the invention, a plurality of rows, that is to say at least two rows, are picked up in one operation from the transfer unit by a pick-up apparatus, in order to deposit these on the motorized conveying unit in a subsequent step. The motorized conveying unit constitutes, for example, a tray or a conveyor belt. In this case, the method according to the invention furthermore allows at least two rows to be successively deposited, which overlap after the deposition. In this way, the number of pick-up processes and the travel of the pick-up apparatus within a production process of a solar module is reduced and the time required for the production method is shortened. The efficiency of the method mentioned in the introduction is thus increased.

In one refinement, provision is made for the remaining rows to remain vertically spaced apart from the solar module. By way of example, two or three rows are picked up simultaneously by the pick-up apparatus and provided above the solar module. In the method according to the invention, the pick-up apparatus is able to move toward the solar module in a vertical direction until a first row, or the row currently to be equipped, contacts the solar module, for example contacts it so as to overlap a previously deposited row, and a second and third row, or the remaining rows, continue to remain vertically spaced apart from the solar module by their vertical spacing when the solar module is contacted by the first row. In this way, the pick-up apparatus can equip the solar module with a row while simultaneously guiding a plurality of rows. In one or more further deposition steps, the solar module can be equipped with the further rows.

In one refinement, provision is made for the rows to be picked up by means of suction grippers which are preferably vertically adjustable counter to a restoring force. By way of example, the solar elements arranged in rows are each picked up by means of at least one suction gripper. In this case, the suction grippers may be arranged in such a way that the suction grippers for the first row protrude in the vertical direction beyond the suction grippers for the second row in the direction of the rows to be picked up. The suction grippers for the second row may in turn protrude vertically beyond suction grippers for a further, third row in the direction of the rows, etc. This enables selective pick-up or selective deposition of an individual row, for example the deposition of the first row without depositing the second row. The suction grippers which are vertically adjustable for example counter to a restoring force allow a further, second row to be picked up and deposited after the first row has been picked up or deposited, in particular prior to one or more further, third rows being picked up or deposited. In other words: this thus allows a plurality of rows to be jointly picked up, in particular with a subsequent selective deposition of the jointly picked-up rows.

In the case of the method of the type mentioned in the introduction, the object mentioned in the introduction is alternatively achieved according to the invention in particular in that two successive rows cover different distances during the equipping process. By way of example, the pick-up apparatus is moved perpendicularly with respect to the rows, i.e. perpendicularly with respect to a longitudinal direction of the rows, during the equipping process. By way of example, a first row and at least a second row are picked up by the pick-up apparatus. In this case, the pick-up apparatus is moved, e.g. displaced in a motorized or mechanical manner, perpendicularly with respect to and relative to the first row for example after the first row has been deposited on the motorized conveying unit and prior to deposition of the second row on the motorized conveying unit. In this way, during the equipping, a movement of the motorized conveying unit is supplemented and/or replaced by a movement of the pick-up apparatus, which moves the rows from the transfer unit onto the conveying unit. This makes it possible for the individual rows to be arranged on the conveying unit in an effective manner in terms of time and space.

Provision is made according to the invention for two successive rows to be picked up in one operation during an equipping process for equipping the solar module. Provision is also made according to the invention for the two successive rows to cover distances of differing length during the equipping process.

In one refinement, provision is made for the solar module to remain positionally fixed during the equipping process with the two successive rows. In other words: in this refinement, the conveying unit is not moved during the equipping. In this refinement, after the first row has been deposited, the pick-up apparatus may move perpendicularly with respect to the deposited first row, in order for the second row for equipping the solar module to be deposited on the conveying unit so as to adjoin and overlap the first row. In this way, the relative arrangement of the rows is determinable or settable at least also by the movement of the pick-up apparatus. As an alternative, the conveying unit is moved during the equipping.

In one refinement, provision is made for the solar module to be moved in a clocked manner between two equipping processes. A clocked movement of the solar module or of the conveying unit may be advantageous during the equipping of the conveying unit with the rows. During the equipping, the rows are aligned with one another and connected to one another on the conveying unit. A clocked forward movement makes it possible to provide space at the equipping location for new rows to be arranged on the conveying unit. It is thus conceivable for the pick-up apparatus to move, in order to successively deposit all the picked-up rows, while the conveying unit moves when the pick-up apparatus is intended to pick up a new load.

In one refinement, provision is made for the solar module to be moved in a clocked manner between two equipping processes, namely between a deposition of the rows which are picked up in the one operation and a deposition of further rows which are picked up in a further operation.

In this way, the relative arrangement of the rows during the equipping is determinable solely by the movement of the pick-up apparatus, while the movement of the conveying unit enables a smaller and thus shorter travel of the pick-up apparatus during the equipping. In this way, the equipping of the conveying unit can be carried out in a simplified, in particular more rapid, manner and with increased precision.

In one refinement, provision is made for the solar module to be moved continuously during the equipping process. In particular, the solar module is moved perpendicularly with respect to the rows during the equipping process. In other words: the conveying unit is moved continuously during the equipping process. In this way, the production process of the solar modules can be further accelerated. This is in particular because a row is moved further during and after the equipping of the module with this row and thus a subsequent method step is reached more rapidly.

In a subsequent method step, the solar modules may be moved, for example, for thermal treatment, i.e. for curing of the adhesive means in a region of thermal action, for example in a furnace. In this case, the solar modules may still be located on the conveying unit. Here, the continuous movement of the conveying unit is advantageous. This is because a clocked movement produces regions of overlap of the thermal action, produced by a different dwell time of the rows of solar cells under thermal action, which results in thermal action which is too strong or too weak and thus a striped pattern. By contrast, in the case of a continuous movement of the solar module or of the conveying unit, the solar module is moved uniformly through a region of thermal action, the adhesive applied to and between the rows curing in said region.

The movement of the conveying system may be compensated by a corresponding movement of the pick-up apparatus during the deposition of a row. In this way, a movement of the conveying unit relative to the pick-up apparatus during the deposition of the row can be prevented. As an alternative, the duration of the deposition process may be selected such that, in particular may be selected to be so short that, the described relative movement during the depositing of the row is negligible.

The object mentioned in the introduction is achieved according to the invention in particular by providing an apparatus for producing solar modules, wherein solar elements are combined to form rows, wherein each row comprises at least two solar elements and wherein the solar modules are constructed from electrically interconnected rows, wherein the apparatus comprises a pick-up apparatus which is designed, for the equipping of the solar module, to pick up at least two rows in one operation and to hold them ready at different heights above the solar module and, for the equipping of the solar module, to lower the rows together in each case only to the extent that only the respective row currently to be equipped contacts the solar module.

In one refinement, provision is made for the pick-up apparatus to be designed to hold the remaining rows vertically spaced apart from the solar module.

In one refinement, provision is made for the pick-up apparatus to comprise suction grippers which are preferably vertically adjustable counter to a restoring force and which are designed to pick up the rows, in particular to jointly pick up the rows in one working step.

The object mentioned in the introduction is achieved according to the invention in particular by providing an apparatus for producing solar modules, wherein solar elements are combined to form rows, wherein each row comprises at least two solar elements and wherein the solar modules are constructed from electrically interconnected rows, wherein the apparatus comprises a pick-up apparatus which is designed to cover different distances for at least two successive rows during the equipping process. To this end, the pick-up apparatus may be displaced in a running direction of the conveying apparatus and/or in the vertical direction, for example in a direction along the rows.

Provision is made according to the invention for the pick-up apparatus to be configured to pick up at least two successive rows in one operation during an equipping process for equipping the solar module.

Provision is also made according to the invention for the pick-up apparatus to be configured to cover distances of differing length for the at least two successive rows during the equipping process.

In one refinement, provision is made for the pick-up apparatus to preferably be movable relative to the solar module during the equipping process, in particular to be movable in a direction transverse to the rows. As an alternative or in addition, the pick-up apparatus may preferably be movable in a direction longitudinally with respect to the rows during the equipping process.

In one refinement, provision is made for the apparatus to comprise a conveying unit for accommodating the solar module and for the apparatus to be designed to hold the conveying unit positionally fixed during the equipping process with the two successive rows.

In one refinement, provision is made for the apparatus to be designed to move the conveying unit in a clocked manner between two equipping processes. In one refinement, provision is made for the apparatus to be designed to move the conveying unit in a clocked manner between two equipping processes, namely between a deposition of the rows which are picked up in the one operation and a deposition of further rows which are picked up in a further operation.

In one refinement, provision is made for the apparatus to be designed to move the conveying unit continuously, in particular during the equipping process.

### BRIEF DESCRIPTION OF THE DRAWINGS

The invention will be described in more detail below on the basis of a plurality of preferred exemplary embodiments.

In the figures:

FIG. 1A shows a three-dimensional view of a first apparatus for producing solar modules

FIG. 1B shows a top view of the first apparatus

FIG. 2A shows a three-dimensional view of a second apparatus for producing solar modules

FIG. 2B shows a top view of the second apparatus

FIG. 2C shows a side view of the second apparatus

FIG. 3A shows a three-dimensional view of a third apparatus for producing solar modules

FIG. 3B shows a top view of the third apparatus

FIG. 3C shows a side view of the second apparatus

FIGS. 4A-H show a first pick-up apparatus, a transfer unit and a conveying unit of the first, second or third apparatus in side views and in different arrangements according to different method steps

FIG. 5A shows a side view of a second pick-up apparatus of the first, second or third apparatus, an

FIG. 5B shows a three-dimensional view of the second pick-up apparatus above a conveying unit of the first, second or third apparatus, and also an exploded illustration of an enlarged detail of the pick-up apparatus.

### DETAILED DESCRIPTION

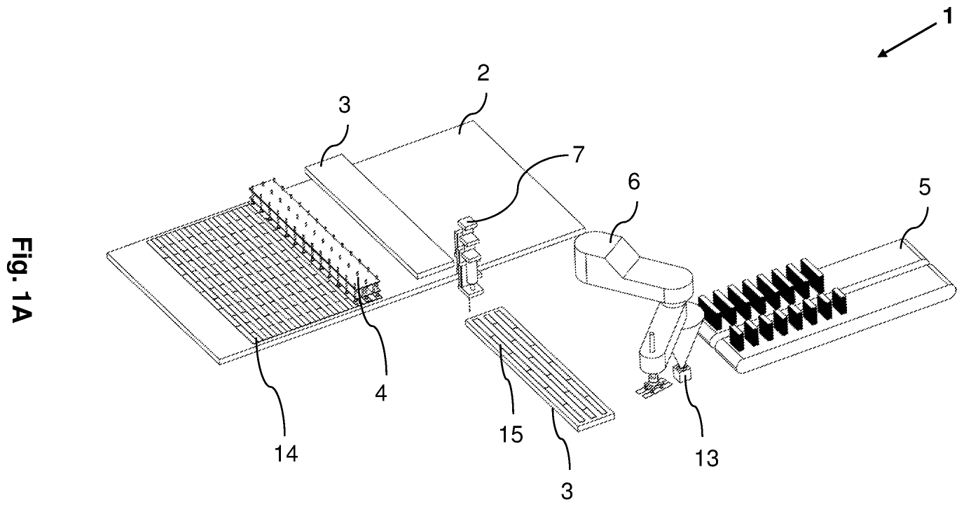

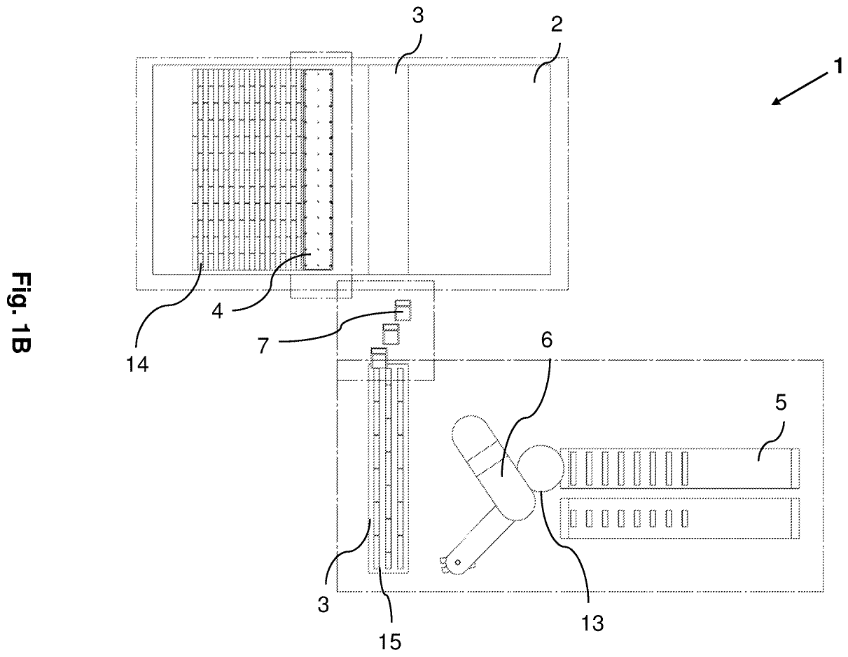

FIG. 1A shows a three-dimensional view of a first apparatus 1 for producing solar modules 14. The apparatus 1 comprises a conveying unit 2, a transfer unit 3 and a pick-up apparatus 4. As illustrated in FIG. 1A, solar elements 15 are arranged on the transfer unit 3, which are combined to form rows. In the present example, the solar elements 15 are of elongate design in the form of what is known as shingle. Solar elements 15 which are strips of a wafer are also referred to as shingle. The rows arranged on the transfer unit 3 are picked up by the pick-up apparatus 4 and deposited onto the conveying unit 2. In one or more preceding steps, the solar elements 15 are provided on a providing unit 5 and placed on the transfer unit 3 by a handling unit 6. The preceding step or steps may be controlled by a monitoring system 13, for example a sensor and/or camera system.

The individual solar elements 15 of different rows may each be arranged on the transfer unit 3 next to one another spaced apart in a direction perpendicular to the rows (or perpendicular to a longitudinal direction of the rows). As an alternative, as illustrated in FIG. 1A, the individual solar elements 15 of different rows may be spaced apart in a transverse direction with respect to the rows and be offset relative to one another in a longitudinal direction with respect to the rows, in what is known as a wall pattern.

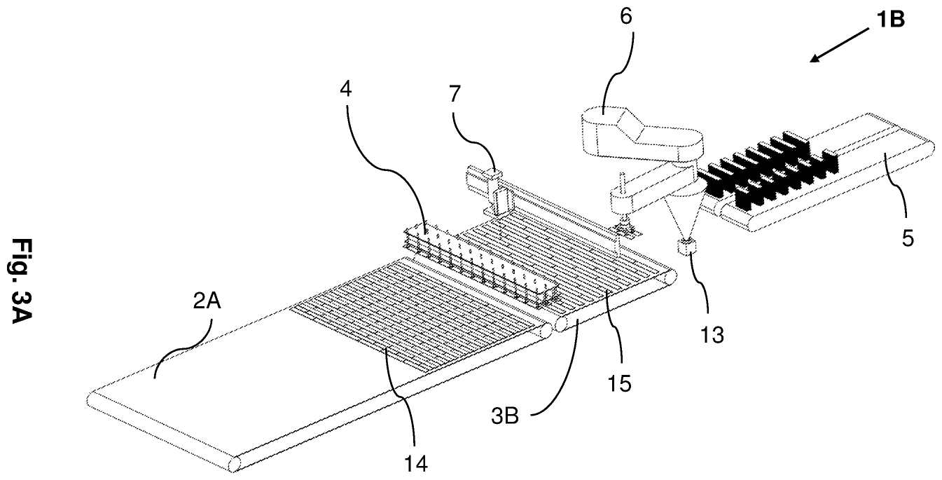

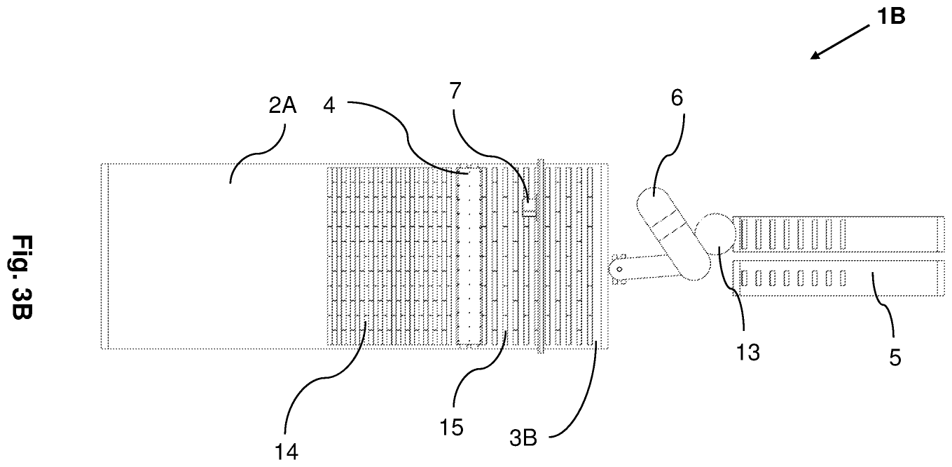

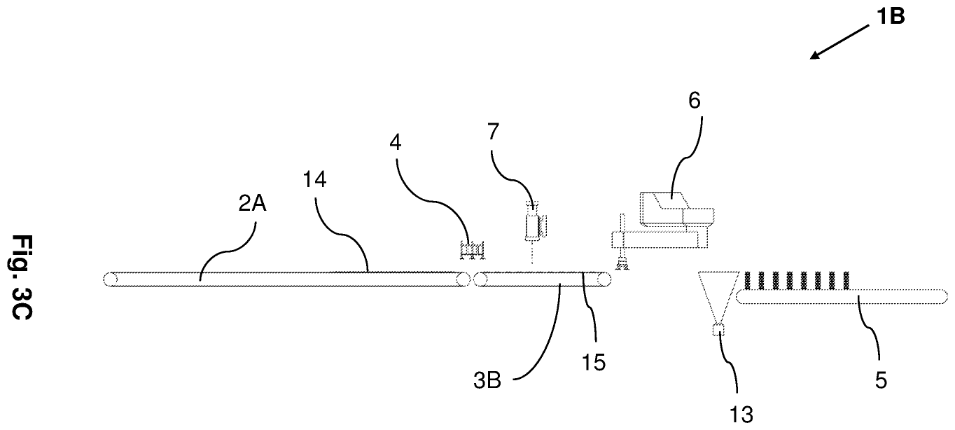

The transfer unit 3 may move parallel, that is to say in a direction along the rows, to the rows deposited on the conveying unit 4. The transfer unit 3 may move relative to the conveying device 4. In this way, the transfer unit 3 can move from a first position, in which the transfer unit 3 is equipped with the solar elements 15 by the handling unit 6, to a second position, in which the rows are picked up by the pick-up apparatus 4 and deposited onto the conveying unit 4. On the way from the first to the second position, the solar elements 15, or the rows, are provided with an adhesive means along at least a longitudinal axis of the rows. The adhesive means is applied by a plurality of delivery units, in the shown example by a plurality of dispensers 7, for example by one dispenser per row. As an alternative, the adhesive means may be applied by only one dispenser 7 (see FIGS. 3A-3C). As an alternative, the adhesive means is applied by means of a printing method, for example screen printing or web-fed printing, by means of printing units, for example screen printing units or web-fed printing units.

After the adhesive means has been applied, the rows arranged on the transfer unit 3 can be connected, on the conveying unit 4, to rows which have already been deposited on said conveying unit. A newly deposited row is connected by virtue of the row to be newly deposited being deposited in a partially overlapping manner on a row which has already been deposited previously, the adhesive means coming into contact both with the row which has already been deposited previously and with the new row to be deposited. In other words, the rows arranged on the conveying unit 4 partially overlap, in particular in a region of the applied adhesive means.

In a subsequent method step, the rows which are arranged on the conveying unit 2 and which are combined to form a solar module 14 can be moved on the conveying unit 2. The conveying unit 2 is, for example, a tray or a conveyor belt. The conveying unit 2 may be a motorized conveying unit. In the next method step, the equipped solar module 14 is guided for example into a region of thermal action, for example into a furnace, in order to cure the adhesive and to thus fixedly connect the rows within the solar module 14 to one another.

The conveying unit 2 may be moved continuously or in a clocked manner during and/or after the equipping process. In particular, the conveying unit 2 can be moved continuously during the equipping process and after the equipping process. As an alternative, the conveying unit 2 may be moved in a clocked manner during the equipping process and continuously after the equipping process.

FIG. 1B shows a top view of the first apparatus 1 from FIG. 1A. Identical or similar features are provided with identical reference designations.

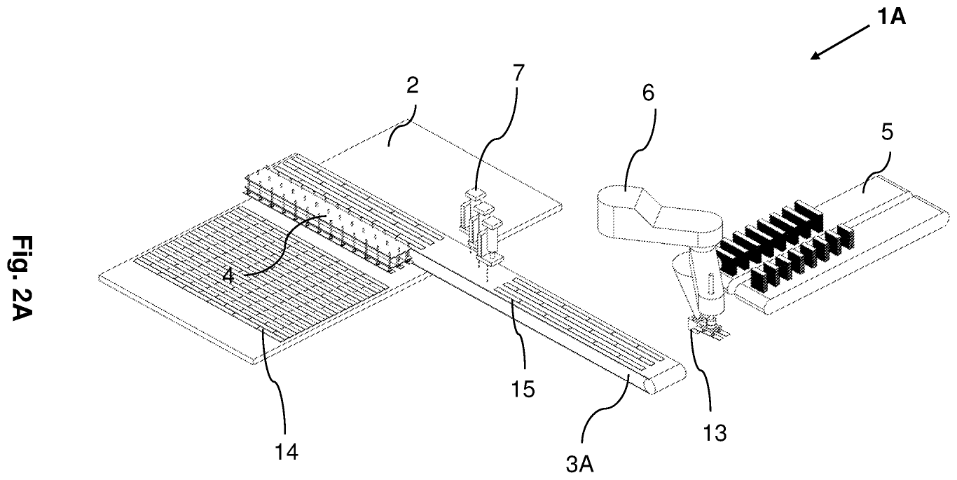

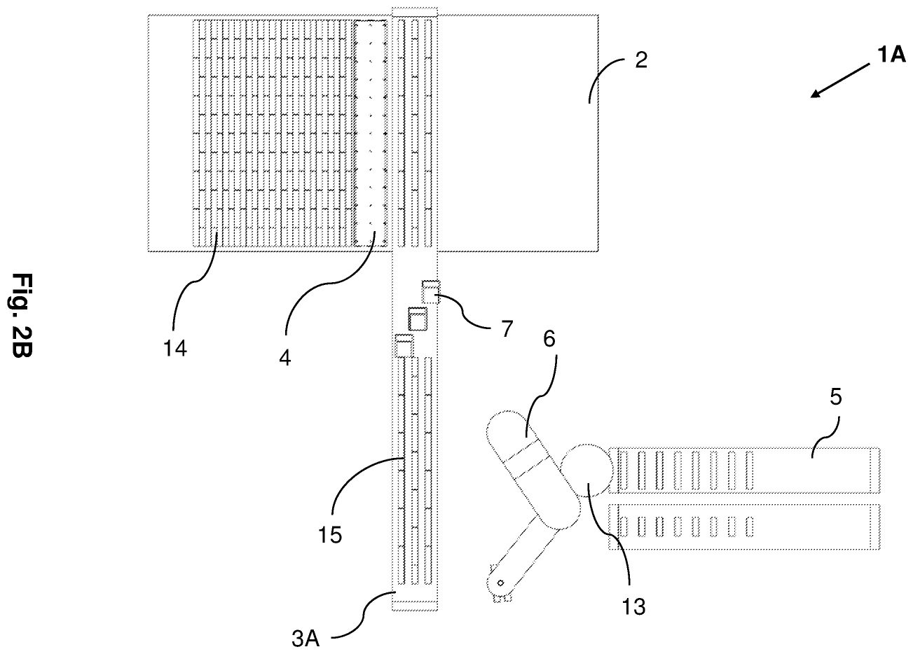

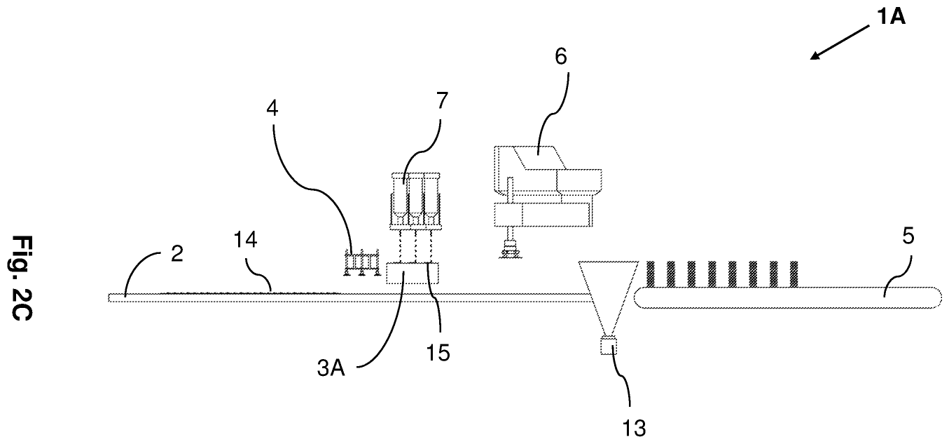

FIG. 2A shows a three-dimensional view of a second apparatus 1A for producing solar modules 14. The second apparatus 1A is similar to the first apparatus 1 shown in FIGS. 1A and 1B. Identical or similar features are provided with identical reference designations. Instead of the transfer unit 3 of the apparatus 1, the apparatus 1A comprises a transfer unit 3A. The transfer unit 3A is designed as a conveyor belt. The conveyor belt extends from the first position, described with reference to FIG. 1, of the transfer unit 3 to the second position of the transfer unit 3. The conveyor belt is movable parallel to the rows arranged thereon and parallel to the rows deposited on the conveying unit 2. In other words, the conveyor belt is movable in a longitudinal direction of the rows. In this way, the solar elements 15 deposited on the transfer unit 3A and arranged in rows can be moved by movement of the conveyor belt from the first position to the second position, from which they are deposited onto the conveying unit 2 by means of the receptacle 4.

FIG. 2B shows a top view of the second apparatus 1A. FIG. 2C shows a side view of the second apparatus 1A. Identical or similar features are provided in each case with identical reference designations.

FIG. 3A shows a three-dimensional view of a third apparatus 1B for producing solar modules 14. The third apparatus 1B is similar to the first apparatuses 1 and second apparatus 1A illustrated in FIGS. 1A-1B and 2A-2C. Identical or similar features are provided with identical reference designations.

Instead of the conveying unit 2 of the first apparatus 1, the apparatus 1B comprises a conveying unit 2A which is designed as a conveyor belt. Instead of the transfer unit 3A of the second apparatus 1A, said transfer unit being shown in FIGS. 2A-2B, the third apparatus 1B comprises a transfer unit 3B which is designed as a conveyor belt. The conveyor belt 3B is movable perpendicularly with respect to the rows which are arranged on the conveyor belt. Correspondingly, the conveying unit 2A, the transfer unit 3B, the handling unit 6 and the providing unit 5 are arranged in a row perpendicularly with respect to the rows on the conveying unit 2A and on the transfer unit 3B.

Similarly to the arrangement of the third apparatus 1B shown in FIG. 3A, it is conceivable for the transfer unit 3 of the first apparatus 1 shown in FIGS. 1A and 1B to be arranged in series with the conveying unit 2, the handling unit 6 and the providing unit 5. In such an arrangement, the transfer unit 3, similarly to the transfer unit 3B, may be movable perpendicularly with respect to the rows arranged on the transfer unit 3 or on the conveying unit 2. As an alternative, in such an arrangement the first position of the transfer unit 3, in which the transfer unit 3 is equipped with the solar elements 15 by the handling unit 6, may correspond to the second position of the transfer unit 3, in which the solar elements 15 are picked up from the transfer unit 3 by the pick-up apparatus 4 and deposited on the conveying unit 2. In this way, the transfer unit would not have to be moved between the loading and unloading thereof. In this case, the arrangement shown in FIG. 3A has, inter alia, the advantage that the transfer unit 3B can simultaneously be unloaded by the pick-up apparatus 4 and loaded by the handling unit 6.

FIG. 3B shows a top view of the third apparatus 1B. FIG. 3C shows a side view of the third apparatus 1B. Identical or similar features are provided in each case with identical reference designations.

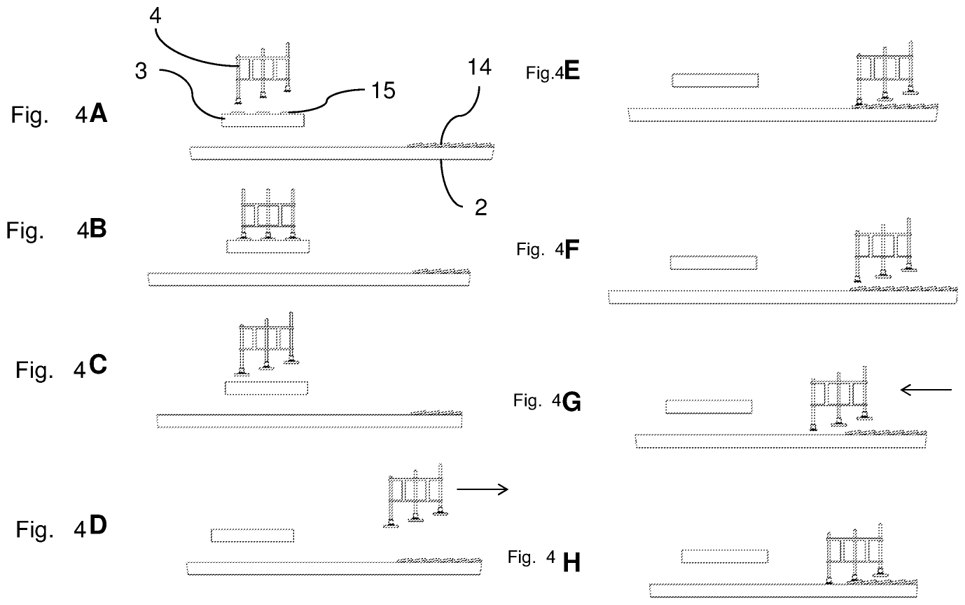

FIG. 4A shows the pick-up apparatus 4, which is arranged above the transfer device 3. The transfer unit 3 is in turn arranged above the conveying unit 2. In other words, the transfer unit 3 is arranged in the second position of the transfer unit 3, said second position being described with reference to FIG. 1. As an alternative, the transfer unit 3 of the first apparatus 1 may be the transfer unit 3A of the second apparatus 1A or the transfer unit 3B of the third apparatus 1B. The conveying unit 2 of the first apparatus 1 may be the conveying unit 2A of the third apparatus 1B.

The pick-up apparatus 4 comprises one or more suction grippers. In the shown example, the pick-up apparatus comprises a plurality of suction grippers which are arranged in rows and by means of which the rows can be picked up by the pick-up apparatus 4. In the shown example, the suction grippers are arranged in three rows. In the shown example, the respective rows of suction grippers extend perpendicularly with respect to the image plane. In this case, the suction grippers are arranged such that a first suction gripper or a plurality of suction grippers arranged in a first row (the left-hand row of suction grippers in FIG. 4) contacts, after a vertical movement of the pick-up apparatus 4 toward the transfer unit 3, a row or one or more solar elements 15 of a row, while one or more other suction grippers of a further row (the suction grippers of the middle and right-hand rows of suction grippers in FIG. 4) are vertically spaced apart from the rows or the solar elements 15.

If the vertical movement of the pick-up apparatus 4 in the direction of the transfer unit 3 is continued, the further suction grippers move toward further rows or further solar elements 15 of further rows. In the case of this further vertical movement, that is to say in the case of a vertical movement in the direction of the transfer unit 3 after the first suction gripper or the first row of suction grippers has already come into contact with a solar cell, this or these first suction grippers is/are adjusted vertically, for example counter to a restoring force. The vertical adjustment of the suction grippers enables a vertical movement of the pick-up apparatus 4 after the suction grippers have come into contact with the solar elements 15, without destroying or damaging the solar elements 15 in the process.

The vertical adjustment makes it possible for the suction grippers to be arranged at the same height relative to one another. The further vertical movement of the pick-up apparatus 4 in the direction of the transfer unit 3 has the result that eventually a number of second suction grippers, in the shown example the middle row of suction grippers, and eventually a number of third suction grippers, in the shown example the right-hand row of suction grippers, each come into contact with further solar elements 15, as illustrated in FIG. 4B.

A vertical movement of the pick-up apparatus 4 away from the transfer unit 3 has the result that the individual contacted solar elements 15 are picked up from the transfer unit 3 by means of the pick-up apparatus 4. The suction grippers are also moved to their original position by the restoring force, such that the suction grippers on different rows have different spacings to the transfer unit 3 and the conveying unit 2. This is illustrated in FIG. 4C. Due to the different vertical arrangement of the suction grippers or rows of suction grippers, the picked-up solar elements 15 or rows are arranged vertically spaced apart at different heights relative to the transfer unit 3 and the conveying unit 2.

The pick-up apparatus 4 is movable in translation in a direction perpendicular to the rows or toward the solar module 14, as illustrated in FIG. 4D. In this way, due to different vertical arrangement of the suction grippers or rows of suction grippers, the picked-up solar elements 15 or rows are arranged vertically spaced apart at different heights relative to the conveying unit 2.

The pick-up apparatus 4 may comprise suction grippers, for example a row of suction grippers, which are not vertically adjustable. By way of example, the row of suction grippers which has the greatest vertical spacing to the transfer unit 3 or to the conveying unit 2 may not be vertically adjustable. In the shown example, this is the right-hand row of suction grippers.

As shown in FIG. 4E, a first row is brought into contact with the conveying unit 2 or with a row which is already arranged on the conveying unit 2, while further rows, in the shown example a middle second and a right-hand third row, are arranged at a vertical spacing above the conveying unit 2 or the solar module 14. In other words: for the equipping of the solar module 14, the rows are lowered together in each case only to the extent that only the respective row currently to be equipped contacts the solar module 14.

A movement of the pick-up apparatus 4 and/or of the conveying unit 2 perpendicularly with respect to the rows or to a longitudinal axis of the rows makes it possible for the further rows picked-up by the pick-up apparatus 4 to be deposited on the conveying unit 2, as illustrated in FIGS. 4G and 4H. In other words: during the equipping process of the solar module 14, the second row (in the shown example the middle row) covers a different, namely a longer, distance than the first row (in the shown example the left-hand row).

It is thus possible, as illustrated in FIGS. 4E-4H, for a second row to be positioned vertically above a suitable deposition position, in order to move the pick-up apparatus 4 vertically in the direction of the conveying unit 2 until the solar elements 15 picked up by the row of second suction grippers contact the conveying unit 2 or the previously deposited row.

In this process, the first row of suction grippers, as shown in FIG. 4H, is contacted by the conveying unit 2. The vertical movement of the pick-up apparatus 4 in the direction of the conveying unit 2, said movement being continued after the conveying unit 2 has come into contact with the first row of suction grippers, leads to a vertical adjustment of the first row of suction grippers.

During the equipping process shown in FIGS. 4D-4H, the solar module 14 or the conveying unit 2 may, for example, remain positionally fixed or move continuously. Between two equipping processes, that is to say between the deposition of the picked-up three rows of solar elements 15 and the deposition of a further three picked-up solar elements 15, the solar module 14 or the conveying unit 2 may move for example continuously and/or in a clocked manner, in order to free up further space on the conveying unit 2 for equipping purposes.

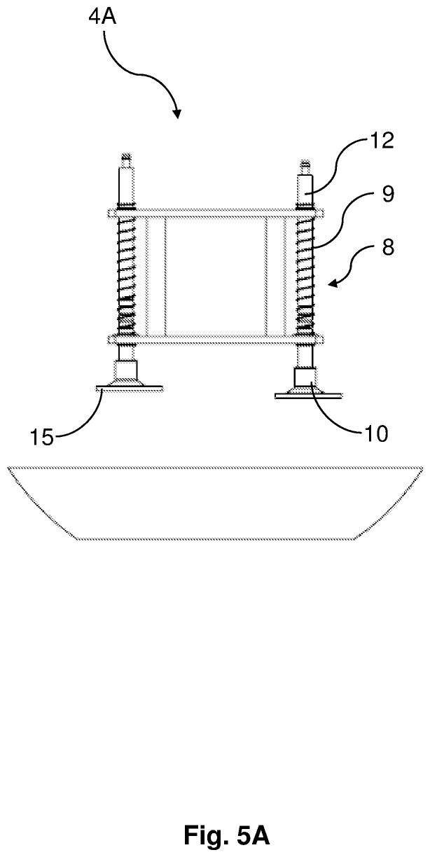

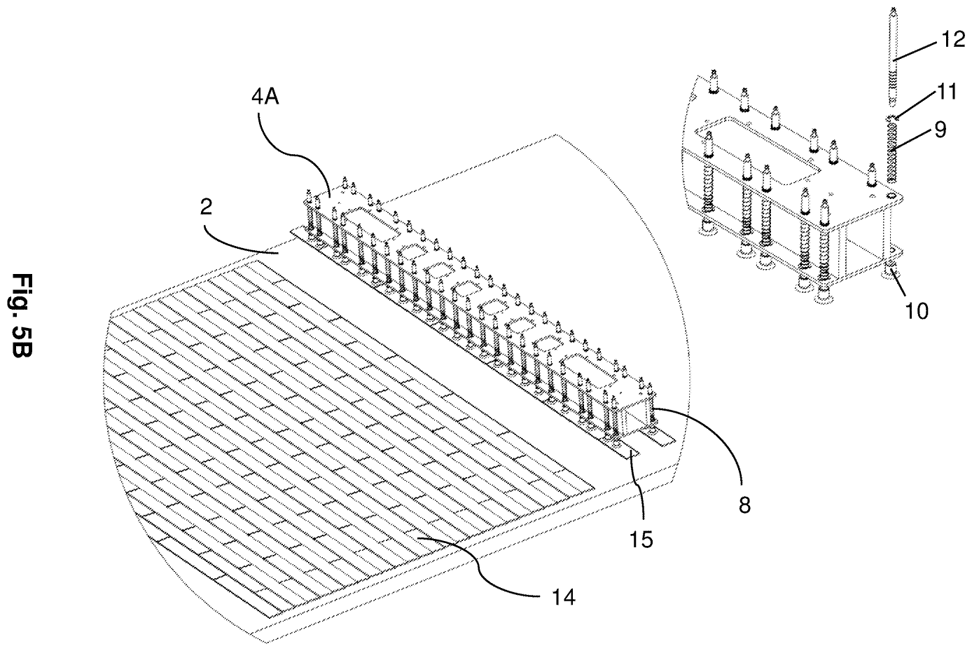

FIG. 5A shows a second pick-up apparatus 4A similar to the first pick-up apparatus 4 shown in FIGS. 1A-4H. The second pick-up apparatus 4A comprises a number of suction grippers 8, which are arranged in two rows in side view. The suction grippers 8 may correspond to the suction grippers of the first pick-up apparatus 4.

The suction grippers 8 arranged in the first row are arranged vertically spaced apart at a first spacing relative to a reference plane arranged under the pick-up apparatus 4A, for example relative to the transfer unit 3 or the conveying unit 2. The suction grippers 8 arranged in the second row are arranged spaced apart at a second spacing relative to the reference plane. The second spacing is greater than the first spacing. The first and the second spacing may be changed by the vertical movement of the pick-up apparatus 4A relative to the reference plane. If in so doing a suction gripper 8 which is arranged in the first row strikes the reference plane and the vertical movement of the pick-up apparatus 4A in the direction of the reference plane is continued, this suction gripper 8 is adjusted vertically, in particular moved relative to the pick-up apparatus 4A. In the shown example, the suction gripper 8 is moved relative to the pick-up apparatus 4A in a direction opposite to the movement direction of the pick-up apparatus 4A, that is to say away from the reference plane. The vertical adjustment is effected counter to a restoring force, which in the shown example is provided by a spring element 9.

The suction grippers 8 each comprise a vacuum suction gripper 10, for example a suction head. The vacuum suction gripper 10 can pick up a solar element 15 by generation of a negative pressure on the surface of the solar element 15 and can deposit it by re-establishment of the ambient pressure or by generation of a positive pressure. The respective pressure state may be provided, for example, by a pumping apparatus (not illustrated) connected to the suction grippers 8.

In a similar manner, the solar elements 15 on the conveying unit 2 or 2A and on the transfer unit 3, 3A or 3B may be held on the respective conveying or transfer unit by generation of a negative pressure on a side (for example facing away from the pick-up apparatus 4 and/or from the handling unit 6) of the solar elements 15. The negative pressure may be provided, for example, via openings in the respective conveying or transfer unit, which are connected to the or a pumping apparatus (not illustrated).

FIG. 5A shows a three-dimensional view of a pick-up apparatus 4A which is arranged above the conveying unit 2. Identical or similar features are provided with identical or similar reference designations. In the shown example, the suction grippers 8 comprise, in addition to the spring element 9, a securing ring 11 and a spring plunger 12.

### LIST OF REFERENCE DESIGNATIONS

1 First apparatus for producing solar modules
1A Second apparatus for producing solar modules
1B Third apparatus for producing solar modules
2 Conveying unit of the first and second apparatus
2A Conveying unit of the third apparatus
3 Transfer unit of the first apparatus
3A Transfer unit of the second apparatus
3B Transfer unit of the third apparatus
4 First pick-up apparatus
4B Second pick-up apparatus
5 Providing unit
6 Handling unit
7 Dispenser
8 Suction gripper
9 Spring element
10 Vacuum suction gripper
11 Securing ring 11
12 Spring plunger
13 Monitoring system

1. A method for producing solar modules (14), the method comprising:
combining solar elements (15) to form rows, each said row comprising at least two solar elements (15);
constructing the solar modules (14) from electrically interconnected ones of the rows, characterized in that,
for the equipping of the solar module (14), picking up at least two rows in one operation and holding the at least two rows ready at different heights above the solar module (14); and
lowering the rows together in each case only to an extent that only the respective row currently to be equipped contacts the solar module (14).

2. The method as claimed in claim 1, further comprising the remaining rows remaining vertically spaced apart from the solar module (14).

3. The method as claimed in claim 1, wherein the rows are picked up suction grippers (8) which are adjustable counter to a restoring force.

4. A method for producing solar modules (14), the method comprising:
combining solar elements (15) are combined to form rows, each said row comprising at least two solar elements (15);
constructing the solar modules (14) from electrically interconnected ones of the rows; and
for the equipping of the solar module (14), picking up at least two successive rows in one operation and the at least two successive rows cover distances of differing length during the equipping process.

5. The method as claimed in claim 4, wherein the solar module (14) remains positionally fixed during the equipping process with the two successive rows.

6. The method as claimed in claim 4, further comprising moving the solar module (14) in a clocked manner between two equipping processes.

7. The method as claimed in claim 4, further comprising moving the solar module (14) is moved continuously during the equipping process.

8. The method as claimed in claim 4, further comprising using strips of a wafer as the solar elements (15).

9. An apparatus for producing solar modules (14) that includes, solar elements (15) that are combined to form rows, and each said row comprises at least two solar elements (15), and the solar modules (14) are constructed from electrically interconnected ones of the rows, the apparatus comprising:
a pick-up apparatus (4, 4A) which is designed, for the equipping of the solar module (14), to pick up at least two of the rows in one operation and to hold the at least two rows ready at different heights above the solar module (14) and to lower the rows together in each case only to extent that only the respective row currently to be equipped contacts the solar module (14).

10. The apparatus as claimed in claim 9, wherein the pick-up apparatus (4, 4A) is designed to hold the remaining rows vertically spaced apart from the solar module (14).

11. The apparatus as claimed in claim 9, wherein the pick-up apparatus (4, 4A) comprises suction grippers (8) which are adjustable counter to a restoring force and which are designed to pick up the rows.

12. The apparatus, as claimed in claim 9, wherein the pick-up apparatus (4, 4A) is designed, for the equipping of the solar module (14), to pick up at least two successive ones of the rows in one operation and to cover distances of differing length for the at least two successive rows during the equipping process.

13. The apparatus as claimed in claim 9, wherein the pick-up apparatus (4, 4A) is movable relative to the solar module (14) during the equipping process in a direction transverse to the rows.

14. The apparatus as claimed in claim 12, further comprising a conveying unit (2, 2A) for accommodating the solar module (14) that holds the conveying unit (2, 2A) positionally fixed during the equipping process with the two successive rows.

15. The apparatus as claimed in claim 14, wherein the conveying unit (2, 2A) is movable in a clocked manner between two equipping processes.

16. The apparatus as claimed in claim 14, wherein the conveying unit (2, 2A) is movable continuously during the equipping process.
